(19) United States
(12) Patent Application Publication
(10) Pub. No.: US 2012/0122269 A1
(43) Pub. Date: May 17, 2012

(54) PLASMA PROCESSING APPARATUS AND METHOD FOR MANUFACTURING PHOTOVOLTAIC ELEMENT USING SAME

(75) Inventor: Akihiro Kuroda, Osaka (JP)

(73) Assignee: Sanyo Electric Co., Ltd., Moriguchi-shi (JP)

(21) Appl. No.: 13/260,503

(22) PCT Filed: Mar. 18, 2010
(86) PCT No.: PCT/JP2010/054632

§ 371 Date: Jan. 25, 2012

(30) Foreign Application Priority Data
Mar. 26, 2009 (JP) 2009-076760
Mar. 26, 2009 (JP) 2009-076862

(51) Int. Cl. H01L 31/20; C23C 16/50

(52) U.S. Cl. 438/96; 118/723 E; 257/E31.048; 257/E31.045

(57) ABSTRACT

A method of manufacturing a photovoltaic element (710) capable of inhibiting the thicknesses and the qualities of formed films from being nonuniform includes steps of forming a substrate-side electrode (712), forming a photoelectric conversion layer (713, 714) with a plasma processing apparatus (1) including a first electrode (3) and a second electrode (4) provided on a portion opposed to the first electrode with a plurality of gas supply ports (4a) formed along concentric circles so that the quantities of gas supplied through the gas supply ports are different from each other on an inner peripheral side and an outer peripheral side, and forming a rear electrode (715).

### TECHNICAL FIELD

The present invention relates to a plasma processing apparatus and a method for manufacturing a photovoltaic element with the same, and more particularly, it relates to a plasma processing apparatus including electrodes arranged to be opposed to each other and a method for manufacturing a photovoltaic element with the same.

### BACKGROUND ART

A plasma processing apparatus including electrodes arranged to be opposed to each other and a method for manufacturing a photovoltaic element with the same are known in general.

In Japanese Patent Laying-Open No. 2008-38200, there are disclosed a plasma processing apparatus including a shower plate (electrode) provided with openings supplying source gas and a stage (electrode) arranged to be opposed to the shower plate and a method for manufacturing a photovoltaic element with the same. The openings supplying the source gas disclosed in Japanese Patent Laying-Open No. 2008-38200 are arranged on a large number of concentric circles, and so formed that the source gas is supplied to a substrate arranged on a side of the stage closer to the shower plate at a uniform rate through the openings of the shower plate.

In Japanese Patent Laying-Open No. 2006-237490, there are disclosed a plasma processing apparatus including a first electrode provided with openings supplying source gas and a second electrode arranged to be opposed to the first electrode and a method for manufacturing a photovoltaic element with the same. The openings supplying the source gas disclosed in Japanese Patent Laying-Open No. 2006-237490 are provided in the form of a matrix, and so formed that the source gas is uniformly supplied to a substrate arranged on a side of the second electrode closer to the first electrode through the openings of the first electrode.

### Prior Art

### Patent Documents

Patent Document 1: Japanese Patent Laying-Open No. 2008-38200
Patent Document 2: Japanese Patent Laying-Open No. 2006-237490

### SUMMARY OF THE INVENTION

### Problems to be Solved by the Invention

In each of the plasma processing apparatuses disclosed in Japanese Patent Laying-Open No. 2008-38200 and Japanese Patent Laying-Open No. 2006-237490, however, such a problem has been confirmed that the thickness and the quality of a film (photoelectric conversion layer) formed on an inner peripheral side of the substrate and the thickness and the quality of a film formed on an outer peripheral side may not be uniformly formed when the source gas is uniformly supplied to the substrate. In the method for manufacturing a photovoltaic element with such a plasma processing apparatus, there is such a problem that the film qualities and the film thicknesses become so nonuniform as described above that output characteristics of the manufactured photovoltaic element are reduced.

The present invention has been proposed in order to solve the aforementioned problems, and is to provide a plasma processing apparatus capable of inhibiting the thicknesses and the qualities of formed films from being nonuniform and a method for manufacturing a photovoltaic element with the same.

### Means for Solving the Problems

In order to attain the aforementioned object, a method for manufacturing a photovoltaic element according to a first aspect of the present invention includes the steps of forming a substrate-side electrode having conductivity on a substrate, forming a photoelectric conversion layer on the substrate-side electrode with a plasma processing apparatus including a first electrode capable of holding the substrate and a second electrode set to be opposed to the first electrode and provided on a portion opposed to the first electrode with a plurality of gas supply ports formed along concentric circles so that the quantities of gas supplied through the gas supply ports are different from each other on an inner peripheral side and an outer peripheral side, and forming a rear electrode having conductivity on the photoelectric conversion layer.

A plasma processing apparatus according to a second aspect of the present invention includes a first electrode capable of holding a substrate and a second electrode set to be opposed to the first electrode and provided on a portion opposed to the first electrode with a plurality of gas supply ports, while the plurality of gas supply ports are provided along concentric circles, and so arranged that the quantities of supplied gas are different from each other on an inner peripheral side and an outer peripheral side.

### Effects of the Invention

In the method for manufacturing a photovoltaic element according to this first aspect, the thicknesses and the qualities of formed films can be inhibited from being nonuniform due to the aforementioned structure.

In the plasma processing apparatus according to the second aspect, a photovoltaic element in which the thicknesses and the qualities of formed films are inhibited from being nonuniform can be manufactured, whereby output characteristics of the photovoltaic element can be inhibited from reduction.

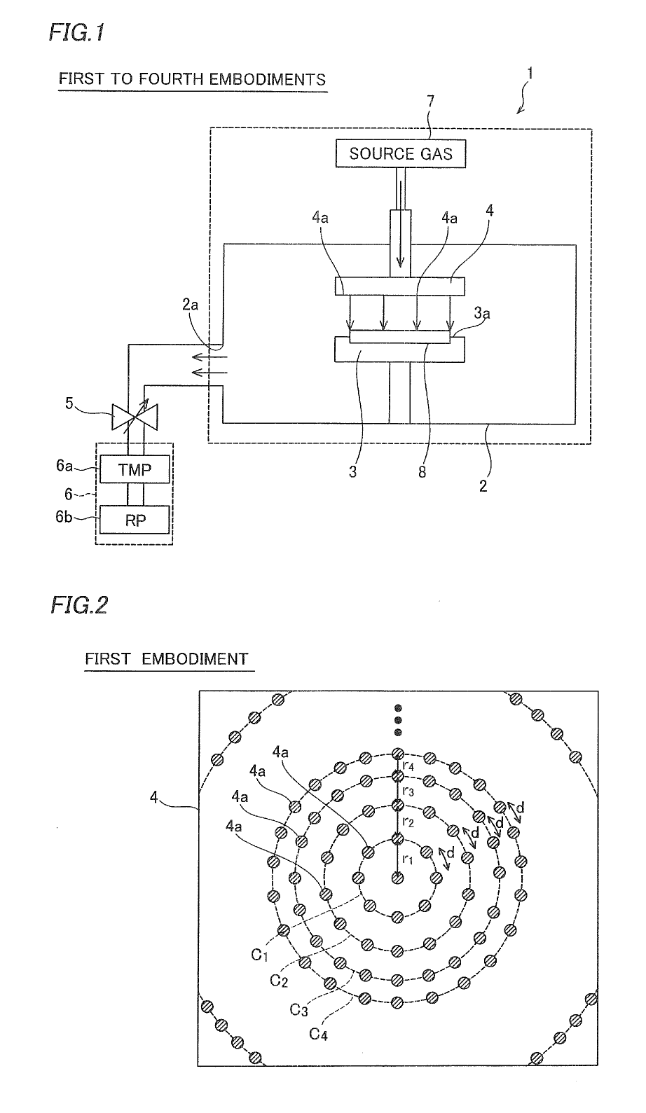

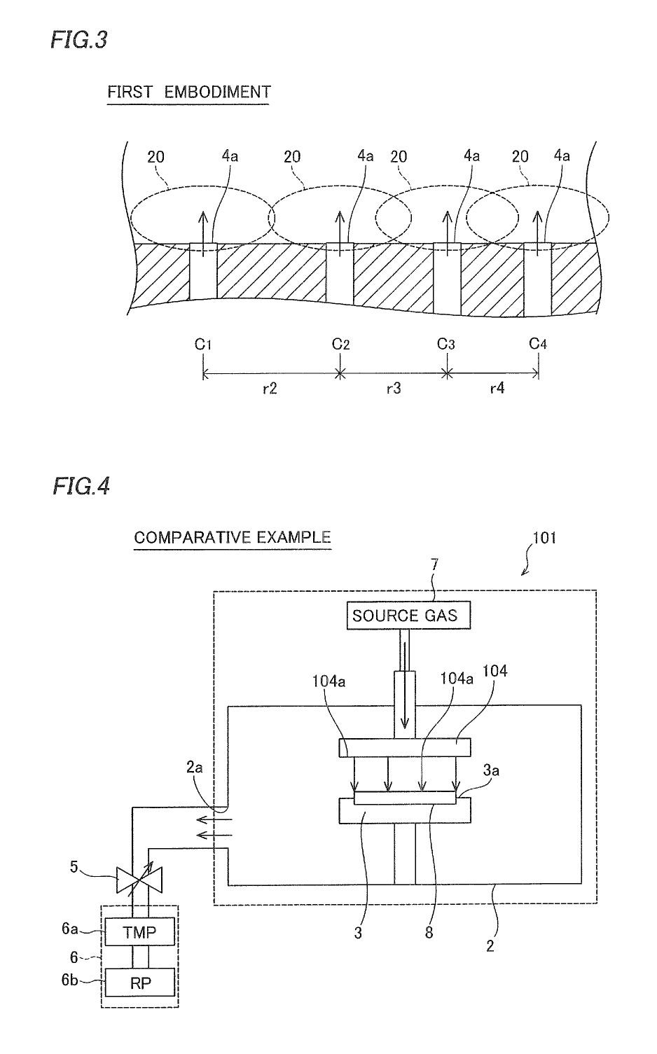

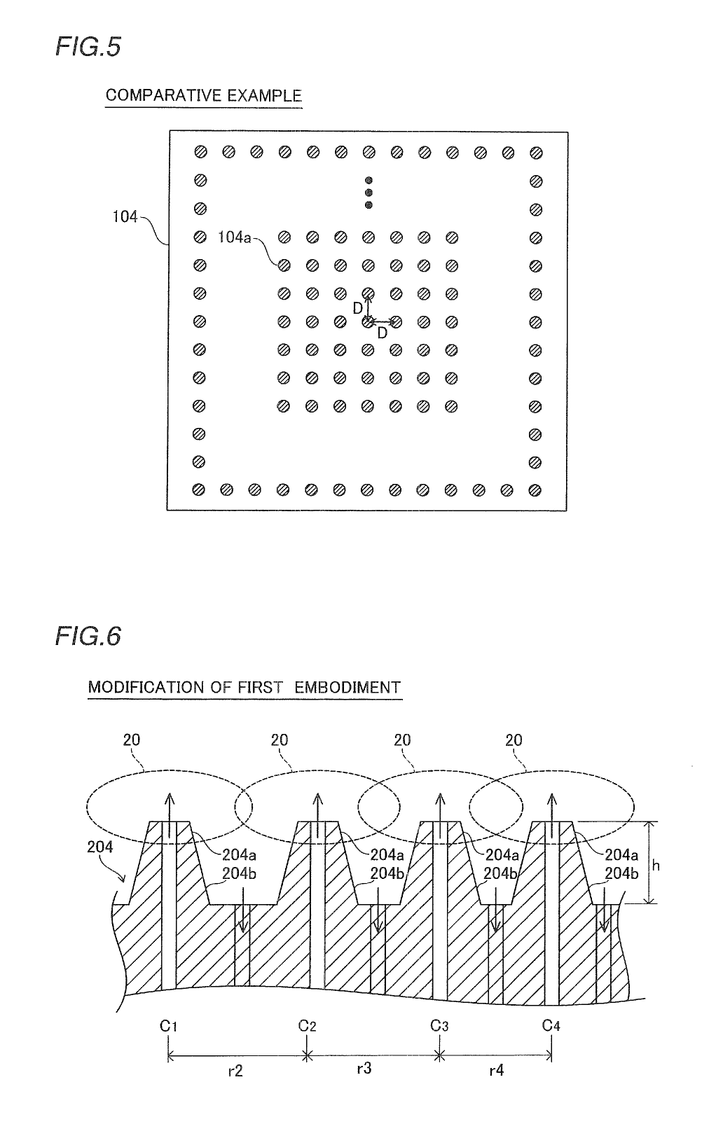

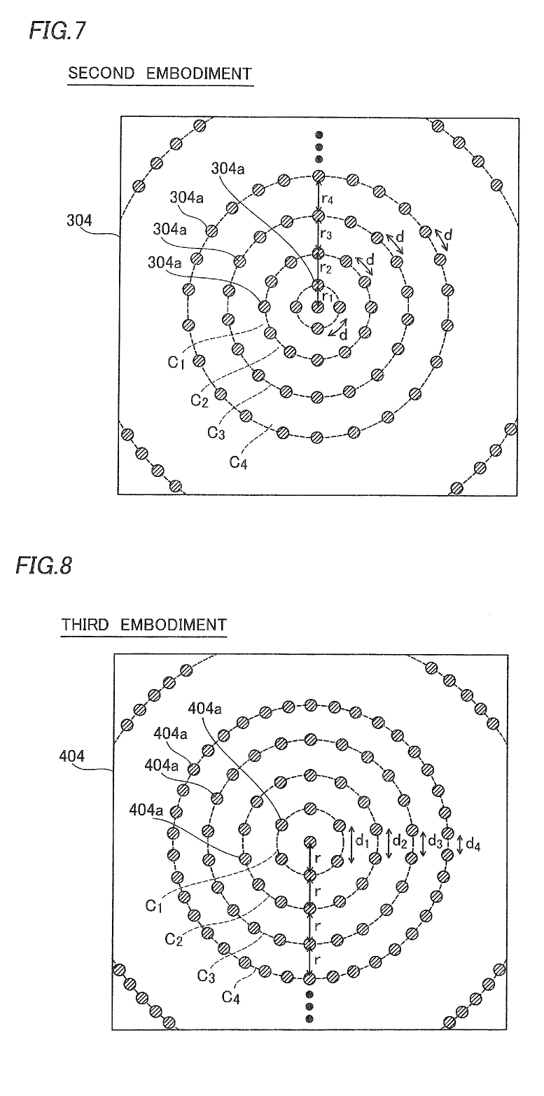

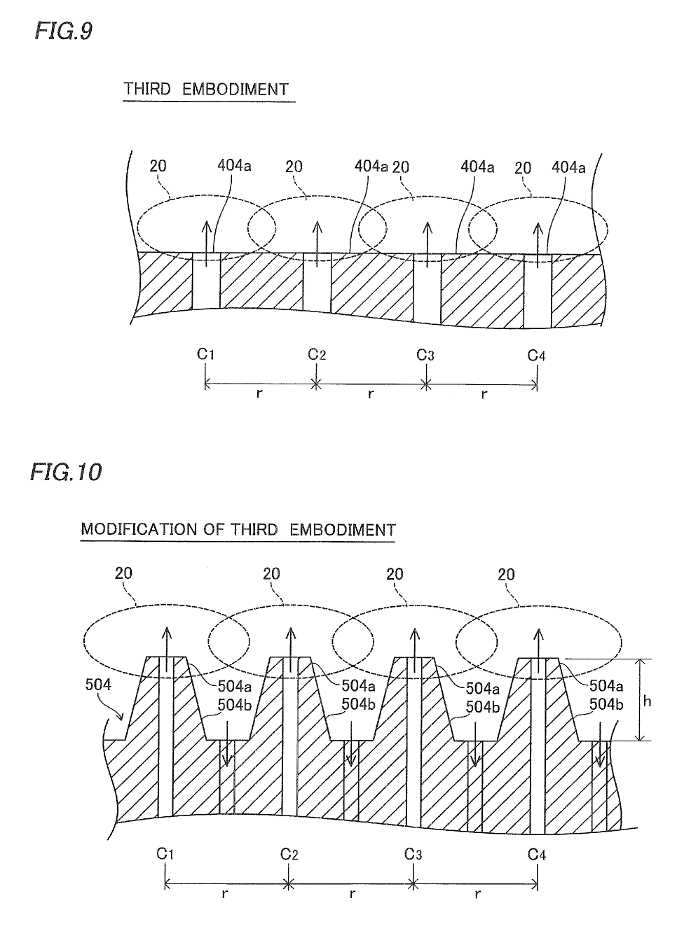

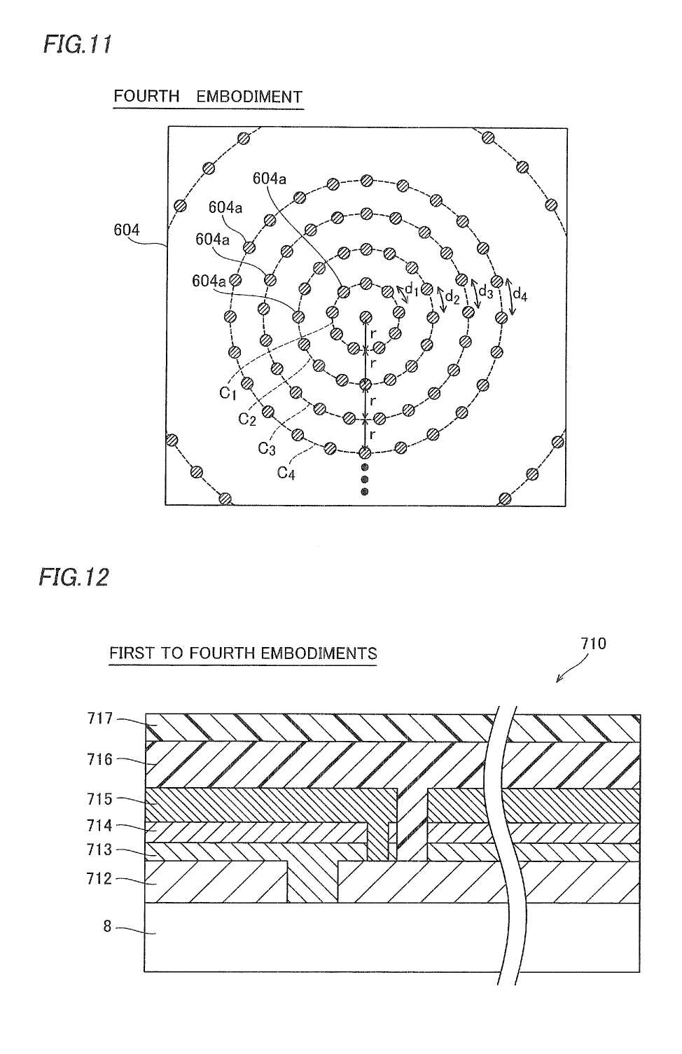

### BRIEF DESCRIPTION OF THE DRAWINGS

[FIG. 1 ] A schematic diagram showing a plasma processing apparatus according to each of first to fourth embodiments of the present invention.

[FIG. 2] A plan view of a second electrode of the plasma processing apparatus according to the first embodiment of the present invention as viewed from below.

[FIG. 3] A sectional view of the second electrode of the plasma processing apparatus according to the first embodiment of the present invention.

[FIG. 4] A schematic diagram showing a plasma processing apparatus according to comparative example.

[FIG. 5] A plan view of a second electrode of the plasma processing apparatus according to comparative example as viewed from below.

[FIG. 6] A sectional view of a second electrode of a plasma processing apparatus according to a modification of the first embodiment of the present invention.

[FIG. 7] A plan view of a second electrode of the plasma processing apparatus according to the second embodiment of the present invention as viewed from below.

[FIG. 8] A plan view of a second electrode of the plasma processing apparatus according to the third embodiment of the present invention as viewed from below.

[FIG. 9] A sectional view of the second electrode of the plasma processing apparatus according to the third embodiment of the present invention.

[FIG. 10] A sectional view of a second electrode of a plasma processing apparatus according to a modification of the third embodiment of the present invention.

[FIG. 11] A plan view of a second electrode of the plasma processing apparatus according to the fourth embodiment of the present invention as viewed from below.

[FIG. 12] A sectional view of a photovoltaic element according to each of the first to fourth embodiments of the present invention.

### MODES FOR CARRYING OUT THE INVENTION

### First Embodiment

A plasma processing apparatus according to a first embodiment of the present invention is described with reference to FIGS. 1 to 3. A plasma processing apparatus 1 includes a vacuum chamber 2, a first electrode 3 and a second electrode 4 provided in the vacuum chamber 2, an exhaust flow regulating valve 5 and an evacuation system 6 connected through an exhaust port 2a provided on a side portion of the vacuum chamber 2, and a source gas supply source 7 connected to the second electrode 4.

The first electrode 3 includes a substrate holding portion 3a holding a substrate 8 subjected to plasma processing. A surface of the substrate 8 opposite to the surface subjected to the plasma processing comes into contact with the first electrode 3. The first electrode 3 is fixed to a prescribed potential.

The second electrode 4 includes a plurality of gas supply ports 4a. Source gas is supplied to the gas supply ports 4a from the source gas supply source 7 described later. High-frequency power is applied to the second electrode 4, to generate plasma due to action with a potential applied to the first electrode 3 and to activate the source gas supplied from the gas supply ports 4a. The activated source gas is so supplied to the substrate 8 held by the first electrode 3 that films responsive to the source gas are formed on the surface of the substrate 8.

The exhaust flow regulating valve 5 is provided between the exhaust port 2a and the evacuation system 6, to control the flow rate of gas discharged from the vacuum chamber 2. The evacuation system 6 is constituted of a combination of a turbo molecular pump (TMP) 6a and an oil-sealed rotary vacuum pump (RP) 6b, for example. Unreacted gas and byproducts such as negative ions, malignant radicals and flakes are discharged from the vacuum chamber 2 by the evacuation system 6.

The source gas supply source 7 is connected to the second electrode 4. The source gas supplied from the source gas supply source 7 is supplied from the plurality of gas supply ports 4a provided on the second electrode 4 toward the substrate 8.

The structure of the second electrode 4 is now described in detail with reference to FIGS. 2 and 3. In the second electrode 4 according to the first embodiment, the plurality of gas supply ports 4a are provided on a quadrangular flat plate. An aluminum plate of about 1.5 m by about 1.5 m, for example, can be employed for the second electrode 4. The gas supply ports 4a may be circles of about 0.5 mm in diameter, for example.

According to the first embodiment, the plurality of gas supply ports 4a are provided along concentric circles. In the second electrode 4, one gas supply port 4a provided at the center of the second electrode 4 centers the concentric circles, as shown in FIG. 2. As to a plurality of gas supply ports 4a provided along each concentric circle, the lengths d of arcs connecting adjacent gas supply ports 4a with each other are substantially equal to each other. The gas supply ports 4a are so provided that the lengths of the arcs connecting the adjacent gas supply ports 4a with each other are d. On the other hand, the distances between adjacent concentric circles in the radial direction are smaller on an outer peripheral side as compared with those on an inner peripheral side. It is assumed that r₁ represents the distance from the center of the concentric circles to a concentric circle C₁ (innermost concentric circle), r₂ represents the distance from the concentric circle C₁ to a concentric circle C₂, r₃ represents the distance from the concentric circle C₂ to a concentric circle C₃, and r₄ represents the distance from the concentric circle C₃ to a concentric circle C₄. At this time, the relation of “r₁>r₂>r₃>r₄” holds between the distances r₁ to r₄. The densities of the gas supply ports 4a arranged on the outer peripheral side of the second electrode 4 are larger than the densities of the gas supply ports 4a arranged on the inner peripheral side. Although not shown in FIG. 2, the gas supply ports 4a are provided on the whole surface of the second electrode 4, as described above.

As shown in FIG. 3, the plurality of gas supply ports 4a provided on the concentric circles C₁, C₂, C₃ and C₄ are so provided that the relation between the distances between the adjacent gas supply ports is r₂>r₃>r₄. Activated regions 20 show states of source gas activated by the plasma in the source gas supplied from the respective gas supply ports 4a. The density of the activated source gas is higher in the vicinity of the concentric circle C₄, as compared with that in the vicinity of the concentric circle C₁.

A plasma processing apparatus 101 according to comparative example is now described with reference to FIGS. 4 and 5.

This plasma processing apparatus 101 according to comparative example includes a first electrode 3 and a second electrode 104 set to be opposed to each other in a vacuum chamber 2, as shown in FIG. 4. A substrate holding portion 3a for holding a substrate 8 is provided on a side of the first electrode 3 opposed to the second electrode 104. A plurality of gas supply ports 104a for supplying source gas are provided on a surface of the second electrode 104 opposed to the first electrode 3, as shown in FIG. 5. The gas supply ports 104a are provided in the form of a matrix in the plane of the second electrode 104 opposed to the first electrode 3. An exhaust port 2a is provided on one side surface of the vacuum chamber 2, while the exhaust port 2a is connected to an evacuation system 6 through an exhaust flow regulating valve 5. This evacuation system 6 is constituted of a turbo molecular pump (TMP) 6a and an oil-sealed rotary vacuum pump (RP) 6b. The gas supply ports 104a of the second electrode 104 are connected to a source gas supply source 7. A structure for discharging the source gas is similar to that in the aforementioned first embodiment.

In the plasma processing apparatus 101, plasma is generated on the whole of the upper surface of the second electrode 104, and the source gas is decomposed by the plasma. In the second electrode 4, the plurality of gas supply ports 104a are provided in the form of a matrix on the side opposed to the first electrode 3, and the distances between adjacent gas supply ports 104a are regular intervals D.

In the plasma processing apparatus 101, the source gas employed for generating film formation species is supplied from the plurality of gas supply ports 104a provided on the second electrode 104 toward the substrate 8 held by the first electrode 3. The plurality of gas supply ports 104a are so provided in the form of a matrix that it is possible to supply the source gas at a uniform rate to the substrate 8 held by the first electrode 3. However, there is such a problem that the thicknesses and the qualities of films obtained with the plasma processing apparatus 101 according to comparative example may not be uniform in a plane of the substrate 8.

As an example of that manufactured with the conventional plasma processing apparatus 101, a photovoltaic element or the like can be listed. The plasma processing apparatus 101 is employed for forming microcrystalline silicon semiconductor films included in the photovoltaic element. According to experiments so far conducted with the plasma processing apparatus 101, it has been confirmed that the thicknesses and the qualities of the microcrystalline silicon semiconductor films tend to change from the center along the radial direction in the plane of the substrate 8. In other words, films are formed with uniform thicknesses and qualities around the center (inner peripheral side) while the same may be formed with nonuniform thicknesses and qualities around the outer periphery (outer peripheral side), particularly around corner portions, when the substrate 8 is quadrangular. At this time, there arises difference in photoelectric conversion efficiency between microcrystalline silicon semiconductor films formed around the outer periphery and those around the center, and hence there has been such a problem that the photoelectric conversion efficiency of the whole of the photovoltaic element formed on the substrate 8 is rate-determined by the microcrystalline silicon semiconductor films having low photoelectric conversion efficiency. This phenomenon more remarkably appears in a case of employing a large-sized substrate 8 exceeding a size of about 1 m by about 1 m.

In the first embodiment, on the other hand, the gas supply ports 4a have been so provided that the distances r₁ to r₄ between the adjacent concentric circles in the radial direction are smaller on the outer peripheral side as compared with those on the inner peripheral side in the second electrode 4. Thus, the supply quantity of the source gas can be increased around the outer periphery as compared with that around the center of the second electrode 4, whereby the density of the activated source gas can be rendered higher around the outer periphery as compared with that around the center of the second electrode 4. Consequently, the supply quantity of the source gas is so controlled that the thicknesses and the qualities of formed films are uniform in the plane of the substrate 8, whereby the thicknesses and the qualities of the films can be inhibited from being nonuniform.

(Modification of First Embodiment)

A modification of the first embodiment is now described with reference to FIG. 6. In a second electrode 204 according to the modification of the first embodiment, a plurality of projecting portions are provided on a quadrangular flat plate while gas supply ports 204a have been provided on the projecting portions, dissimilarly to the first embodiment in which the gas supply ports 204a have been provided on the quadrangular flat plate.

As to the projecting portions provided with the gas supply ports 204a, the distance h from forward end portions to bottom surfaces is about 10 mm. The forward end portions of the projecting portions are so formed that the widths are reduced from base portions toward the forward end portions. Thus, it becomes possible to more concentrate electric fields on the forward end portions of the projecting portions, whereby it becomes possible to generate plasma of a higher density. The gas supply ports 204a provided on the projecting portions are so arranged that activated regions 20 overlap with each other between adjacent gas supply ports 204a.

In a case of employing the second electrode 204 according to the modification of the first embodiment, gas suction ports 204b are preferably provided on recess portions formed between adjacent projecting portions. The gas suction ports 204b are connected to an unshown evacuation system, to suck unreacted gas present in the vicinity of the second electrode 4 and byproducts such as negative ions, malignant radicals and flakes formed by decomposition of source gas. The gas suction ports 204b are so provided that unnecessary byproducts not contributing to plasma generation can be sucked.

### Second Embodiment

A plasma processing apparatus according to a second embodiment of the present invention is now described with reference to FIG. 7. A plurality of gas supply ports 304a according to this second embodiment are provided along concentric circles. In a second electrode 304, one gas supply port 304a provided at the center of the second electrode 304 centers the concentric circles. As to a plurality of gas supply ports 304a provided along each concentric circle, the lengths of arcs connecting adjacent gas supply ports 304a with each other are substantially equal to each other. The gas supply ports 304a are so provided that the lengths of the arcs connecting the adjacent gas supply ports 304a with each other are d. On the other hand, the distances between adjacent concentric circles in the radial direction are set to be smaller on an outer peripheral side as compared with those on an inner peripheral side. In the second embodiment, it is assumed that r₁ represents the distance from the center of the concentric circles to a concentric circle C₁ (innermost concentric circle), r₂ represents the distance from the concentric circle C₁ to a concentric circle C₂, r₃ represents the distance from the concentric circle C₂ to a concentric circle C₃, and r₄ represents the distance from the concentric circle C₃ to a concentric circle C₄. At this time, the relation of “r₁<r₂<r₃<r₄” holds between the distances r₁ to r₄. The densities of the gas supply ports 304a arranged on the inner peripheral side of the second electrode 304 are larger than the densities of the gas supply ports 304a arranged on the outer peripheral side. Although not shown in FIG. 7, the gas supply ports 304a are provided on the whole surface of the second electrode 304, as described above.

In the second electrode 304 according to the second embodiment, the gas supply ports 304a are so provided that the lengths of the arcs connecting the adjacent gas supply ports 304a with each other are substantially equal to each other and the distances between the adjacent concentric circles in the radial direction are larger in the concentric circles on the outer peripheral side as compared with the concentric circles on the inner peripheral side. Therefore, the supply quantity of source gas can be increased around the center as compared with that around the outer periphery of the second electrode 304. Thus, the density of activated source gas can be rendered higher around the center as compared with that around the outer periphery of the second electrode 304.

### Third Embodiment

A plasma processing apparatus according to a third embodiment of the present invention is now described with reference to FIGS. 8 and 9. A plurality of gas supply ports 404a are provided along concentric circles. In a second electrode 404, one gas supply port 404a provided at the center of the second electrode 404 centers the concentric circles, as shown in FIG. 8. The intervals r between adjacent concentric circles are equal to each other. As to a plurality of gas supply ports 404a provided along each concentric circle, on the other hand, the lengths of arcs connecting adjacent gas supply ports 404a with each other are different between concentric circles on an inner peripheral side and concentric circles on an outer peripheral side. In the third embodiment, it is assumed that the lengths of the arcs connecting the adjacent gas supply ports 404a with each other are d₁ in a concentric circle C₁ (innermost concentric circle), d₂ in a concentric circle C₂, d₃ in a concentric circle C₃, and d₄ in a concentric circle C₄. At this time, the relation of “d₁>d₂>d₃>d₄” holds between the distances d₁ to d₄. Although not shown in FIG. 8, the gas supply ports 404a are provided on the whole surface of the second electrode 404.

As shown in FIG. 9, the plurality of gas supply ports 404a provided on the concentric circles C₁, C₂, C₃ and C₄ are so provided that the distances between adjacent gas supply ports are r. Activated regions 20 show states of source gas activated by plasma in source gas supplied from the respective gas supply ports 404a. The lengths of the arcs connecting the adjacent gas supply ports 404a with each other are smaller in the concentric circles on the outer peripheral side as compared with the concentric circles on the inner peripheral side as described above, whereby the density of the activated source gas becomes higher in the vicinity of the concentric circle C₄ as compared with that in the vicinity of the concentric circle C₁. The densities of the gas supply ports 4a arranged on the outer peripheral side of the second electrode 404 are larger than the densities of the gas supply ports 404a arranged on the inner peripheral side.

According to the third embodiment, as hereinabove described, the gas supply ports 404a have been so provided that the intervals between the adjacent concentric circles are substantially equal to each other and the lengths of the arcs connecting the adjacent gas supply ports 404a with each other are smaller in the concentric circles on the outer peripheral side as compared with the concentric circles on the inner peripheral side in the second electrode 404. Thus, the supply quantity of the source gas can be increased around the outer periphery as compared with that around the center of the second electrode 404, whereby the density of the activated source gas can be rendered higher around the outer periphery as compared with that around the center of the second electrode 404.

(Modification of Third Embodiment)

A plasma processing apparatus according to a modification of the third embodiment of the present invention is now described with reference to FIG. 10. In a second electrode 504 according to this modification of the third embodiment, a plurality of projecting portions are provided on a quadrangular flat plate while gas supply ports 504a have been provided on the projecting portions, dissimilarly to the aforementioned third embodiment in which the gas supply ports 504a have been provided on a quadrangular flat plate.

As to the projecting portions provided with the gas supply ports 504a, the distance h from forward end portions to bottom surfaces is about 10 mm. The forward end portions of the projecting portions are so formed that the widths are reduced from base portions toward the forward end portions. Thus, it becomes possible to more concentrate electric fields on the forward end portions of the projecting portions, whereby it becomes possible to generate plasma of a higher density. The gas supply ports 504a provided on the projecting portions are so arranged that activated regions 20 overlap with each other between adjacent gas supply ports 504a.

In a case of employing the second electrode 504 according to the modification of the third embodiment, gas suction ports 504b may be provided on recess portions formed between adjacent projecting portions. The gas suction ports 504b are connected to an unshown evacuation system, to suck unreacted gas present in the vicinity of the second electrode 504 and byproducts such as negative ions, malignant radicals and flakes formed by decomposition of source gas. The gas suction ports 504b are so provided that unnecessary byproducts not contributing to plasma generation can be sucked.

### Fourth Embodiment

A plasma processing apparatus according to a fourth embodiment of the present invention is now described with reference to FIG. 11. A plurality of gas supply ports 604a according to this fourth embodiment are provided along concentric circles. In a second electrode 604, one gas supply port 604a provided at the center of the second electrode 604 centers the concentric circles. Intervals between adjacent concentric circles are set to be equal to each other. As to a plurality of gas supply ports 604a provided along each concentric circle, on the other hand, the lengths of arcs connecting adjacent gas supply ports 604a with each other are different between the concentric circles on an inner peripheral side and the concentric circles on an outer peripheral side. In the fourth embodiment, it is assumed that the lengths of the arcs connecting the adjacent gas supply ports 604a with each other are d₁ in a concentric circle C₁ (innermost concentric circle), d₂ in a concentric circle C₂, d₃ in a concentric circle C₃, and d₄ in a concentric circle C₄. At this time, the relation of “d₁<d₂<d₃<d₄” holds between the distances d₁ to d₄. The densities of the gas supply ports 604a arranged on the outer peripheral side of the second electrode 604 are larger than the densities of the gas supply ports 604a arranged on the inner peripheral side. Although not shown in FIG. 11, the gas supply ports 604a are provided on the whole surface of the second electrode 604.

According to the fourth embodiment, as hereinabove described, the gas supply ports 604a have been so provided that the intervals between the adjacent concentric circles are substantially equal to each other and the lengths of the arcs connecting the adjacent gas supply ports 604a with each other are larger in the concentric circles on the outer peripheral side as compared with the concentric circles on the inner peripheral side. Thus, the supply quantity of source gas can be increased around the center as compared with that around the outer periphery of the second electrode 604, whereby the density of activated source gas can be rendered higher around the center as compared with that around the outer periphery of the second electrode 604.

The structure of a photovoltaic element manufactured with the plasma apparatus 1 according to each of the aforementioned first to fourth embodiments is now described with reference to FIG. 12.

In a photovoltaic element 710 manufactured with the plasma processing apparatus 1 according to each of the first to fourth embodiments, a transparent electrode 712, a first photoelectric conversion layer 713, a second photoelectric conversion layer 714, a rear electrode 715, a filler layer 716 and a rear film 717 are successively stacked on a substrate 8.

The substrate 8 is a single substrate of the photovoltaic element, and a translucent member of glass or the like, for example.

The transparent electrode 712 is constituted of a laminate of one type or a plurality of types selected from metal oxides such as ZnO and SnO₂. ZnO has high light transmission properties, low resistance and flexibility and is at a low cost, and hence the same is preferable as the material for the transparent electrode.

The first photoelectric conversion layer 713 includes amorphous silicon semiconductor films, and the second photoelectric conversion layer 714 includes microcrystalline silicon semiconductor films. In this specification, it is assumed that the term “microcrystalline” denotes not only a complete crystalline state, but also a state partially including an amorphous state. The first photoelectric conversion layer 713 and the second photoelectric conversion layer 714 are thin film photoelectric conversion layers having photoelectric conversion thin films.

The first photoelectric conversion layer 713 is formed by successively stacking p-i-n amorphous silicon semiconductor films, and the second photoelectric conversion layer 714 is formed by successively stacking p-i-n microcrystalline silicon semiconductor films. A tandem type photovoltaic element employing such amorphous silicon semiconductor films and microcrystalline silicon semiconductor films has a structure obtained by stacking two types of semiconductor films having different light absorption waveforms, and can effectively utilize a sunlight spectrum.

An unshown transparent conductive film is preferably formed between the first photoelectric conversion layer 713 and the second photoelectric conversion layer 714. At this time, the transparent conductive film is prepared from a metal oxide such as ZnO having light transmission properties and electrical conductivity.

The rear electrode 715 is preferably made of a material having high light reflectivity, and constituted of a member of Ag or the like exhibiting high light reflectivity and having conductivity. Thus, the photovoltaic element is formed by successively stacking the transparent electrode 712, the first photoelectric conversion layer 713, the second photoelectric conversion layer 714 and the rear electrode 715 on the substrate 8.

The rear film 717 is arranged on the photovoltaic element through the filler layer 716. The rear film 717 is constituted of a resin film of PET or the like. Alternatively, the rear film 717 may have such a structure that resin films or the like hold a metal foil, or may be made of a simple substance or a metal (steel plate) such as SUS or galvalume. The rear film 717 has a function of preventing external penetration of moisture. The filler layer 716 is constituted of resin such as EVA. The filler layer 716 has functions as an adhesive and a buffer for the rear film 717 and the photovoltaic element.

The aforementioned photovoltaic element 710 generates power by light incident from the side of the substrate 8. Power is generated in each of the first photoelectric conversion layer 713 and the second photoelectric conversion layer 714 due to the incident light. The first photoelectric conversion layer 713 and the second photoelectric conversion layer 714 are serially connected with each other, whereby photovoltaic power is generated between the transparent electrode 712 and the rear electrode 715. A photovoltaic element generating high-power photovoltaic power can be manufactured by forming a plurality of photovoltaic elements on the substrate 8 and successively connecting the transparent electrode 712 of one of two adjacent photovoltaic elements and the rear electrode 715 of the other one with each other.

A method for manufacturing the photovoltaic element 710 shown in FIG. 12 is now described.

The transparent electrode 712 made of ZnO having a thickness of about 600 nm is formed on the substrate 8 employing glass having a thickness of about 4 mm by sputtering. Thereafter a YAG laser is applied from a side of the substrate 8 closer to the transparent electrode 712, to oblongly pattern the transparent electrode 712. An Nd:YAG laser having a wavelength of about 1.06 μm, an energy density of about 13 J/cm³ and a pulse frequency of about 3 kHz is employed for this laser separation.

Then, the first photoelectric conversion layer 713 consisting of the amorphous silicon semiconductor films is formed by plasma CVD. More specifically, a p-type amorphous silicon semiconductor film having a thickness of about 10 nm, an i-type amorphous silicon semiconductor film having a thickness of about 300 nm and an n-type amorphous silicon semiconductor film having a thickness of about 20 nm are formed from mixed gas of SiH₄, CH₄, H₂ and B₂H₆, from mixed gas of SiH₄ and H₂ and from mixed gas of SiH₄, H₂ and PH₄ respectively by plasma CVD and successively stacked in the first photoelectric conversion layer 713.

Then, the second photoelectric conversion layer 714 consisting of the microcrystalline silicon semiconductor films is formed by plasma CVD. More specifically, a p-type microcrystalline silicon semiconductor film having a thickness of about 10 nm, an i-type microcrystalline silicon semiconductor film having a thickness of about 2000 nm and an n-type microcrystalline silicon semiconductor film having a thickness of about 20 nm are formed from mixed gas of SiH₄, H₂ and B₂H₆, from mixed gas of SiH₄ and H₂ and from mixed gas of SiH₄, H₂ and PH₄ respectively with the plasma processing apparatus according to the present invention and successively stacked in the second photoelectric conversion layer 714. Table 1 shows the details of various conditions of the plasma CVD at the time of forming the first photoelectric conversion layer 713 and the second photoelectric conversion layer 714.

TABLE 1

| | | Substrate | | | | |
|---|---|---|---|---|---|---|
| | | Temper- | Gas Flow | Reaction | RF | Film |
| | | ature | Rate | Pressure | Power | Pressure |
| | Layer | (° C.) | (sccm) | (Pa) | (W) | (nm) |
| Amor- | p | 180 | SiH₄: 300 | 106 | 10 | 10 |
| phous | Layer | | CH₄: 300 | | | |
| Si Film | | | H₂: 2000 | | | |
| | | | B₂H₆: 3 | | | |
| | i | 200 | SiH₄: 300 | 106 | 20 | 300 |
| | Layer | | H₂: 2000 | | | |
| | n | 180 | SiH₄: 300 | 133 | 20 | 20 |
| | Layer | | H₂: 2000 | | | |
| | | | PH₄: 5 | | | |
| Micro- | p | 180 | SiH₄: 10 | 106 | 10 | 10 |
| crystal- | Layer | | H₂: 2000 | | | |
| line | | | B₂H₆: 3 | | | |
| Si Film | i | 200 | SiH₄: 100 | 133 | 20 | 2000 |
| | Layer | | H₂: 2000 | | | |
| | n | 200 | SiH₄: 10 | 133 | 20 | 20 |
| | Layer | | H₂: 2000 | | | |
| | | | PH₄: 5 | | | |

The first photoelectric conversion layer 713 and the second photoelectric conversion layer 714 are oblongly patterned by applying a YAG laser from the side of the transparent electrode 712. At this time, the distance between the patterned position of the transparent electrode 712 and the position irradiated with the YAG laser is about 50 μm. An Nd:YAG laser having an energy density of about 0.7 J/cm³ and a pulse frequency of about 3 kHz is employed for this laser separation.

Then, the rear electrode 715, containing Ag, having a thickness of about 200 nm is formed on the second photoelectric conversion layer 714 by sputtering. The rear electrode 715 is formed also on regions where the first photoelectric conversion layer 713 and the second photoelectric conversion layer 714 have been removed by the patterning.

Parts of the rear electrode 715 and the second photoelectric conversion layer 714 are oblongly patterned by applying a YAG laser from the side of the rear electrode 715. At this time, the distance between the patterned positions of the first photoelectric conversion layer 713 and the second photoelectric conversion layer 714 and the position irradiated with the YAG laser is about 50 μm. An Nd:YAG laser having an energy density of about 0.7 J/cm³ and a pulse frequency of about 3 kHz is employed for this laser separation.

Then, the filler layer 716 and the rear film 717 are successively arranged on the rear electrode 715. EVA is preferably employed as the filler layer 716, and a PET film is preferably employed as the rear film 717. After arranging the filler layer 716 and the rear film 717, heat treatment is performed with a laminating apparatus at about 150° C. for about 30 minutes, thereby crosslinking, stabilizing and vacuum-bonding the filler layer 716 made of EVA. After the rear film 717 is arranged, the photovoltaic element formed on the substrate 8 is mounted on an unshown frame made of a metal such as aluminum.

In the photovoltaic element manufactured according to the present invention, the second photoelectric conversion layer 714 consisting of the microcrystalline silicon semiconductor films is so formed by the plasma processing apparatus according to the present invention that the thicknesses and the qualities of the microcrystalline silicon semiconductor films can be inhibited from being nonuniform. The second electrode 4 according to the first embodiment of the present invention is so employed that the density of the activated source gas can be rendered higher around the outer periphery as compared with that around the center in the plane of the substrate 8. This is so utilized that the film thicknesses and the film qualities of the second photoelectric conversion layer 714 consisting of the microcrystalline silicon semiconductor films in the plane of the substrate 8 can be inhibited from being nonuniform.

It is considered better that the number of unnecessary byproducts not contributing to film formation is small around the substrate 8 when forming the microcrystalline silicon semiconductor films. The number of the unnecessary byproducts is larger around the outer periphery as compared with that around the center of the substrate 8. This is because the unnecessary byproducts caused by generating the plasma around the center flow into a portion around the outer periphery of the substrate 8. Around the outer periphery of the substrate 8 where the rate of the unnecessary byproducts increases, therefore, it is preferable to increase the supply rate of the source gas thereby increasing the density of the activated source gas.

Further, the second photoelectric conversion layer 714 is preferably formed by the plasma processing apparatus according to the modification of the first embodiment of the present invention or the modification of the third embodiment. The second electrode 204 (504) is provided with the projecting portions, whereby electric fields concentrate on the forward ends of the projecting portions and the plasma density becomes higher.

Consequently, the quantity of the activated source gas supplied to the substrate 8 can be increased, and the film formation rate of the second photoelectric conversion layer 714 can be increased. While the second photoelectric conversion layer 714 is made of a microcrystalline silicon semiconductor, it is difficult to increase the film formation rate for the microcrystalline silicon semiconductor. However, it becomes possible to form the second photoelectric conversion layer 714 at a high rate thereby reducing the manufacturing cost for the photovoltaic element by employing the modification of the first embodiment of the present invention or the modification of the third embodiment.

On the other hand, the plasma processing apparatus according to the present invention is preferably employed for formation of the first photoelectric conversion layer 713 consisting of the amorphous silicon semiconductor films. It is considered that not only the source gas supplied from the gas supply ports 4a (204a, 304a, 404a, 504a, 604a) but also byproducts after the plasma generation contribute to the film formation at the time of forming the amorphous silicon semiconductor films. Therefore, the supply quantity of the source gas to the central portion of the substrate 8 is so increased that the byproducts formed thereon can be diffused from a portion around the center of the substrate 8 to the portion around the outer periphery. Thus, the byproducts can be supplied to the whole of the surface of the substrate 8, and the film thicknesses and the film qualities of the first photoelectric conversion layer 713 consisting of the amorphous silicon semiconductor films can be inhibited from becoming nonuniform.

The first to fourth embodiments of the present invention are not restricted to the formation of the microcrystalline silicon semiconductor films or the formation of the amorphous silicon semiconductor films. When it is desired to increase the supply quantity of the source gas around the outer periphery of the second electrode in film formation employing the plasma processing apparatus, the first and third embodiments of the present invention are preferably applied. When it is desired to increase the supply quantity of the source gas around the center of the second electrode, the second and fourth embodiments of the present invention are preferably applied.

1. A method for manufacturing a photovoltaic element comprising the steps of:
forming a substrate-side electrode having conductivity on a substrate;
forming a photoelectric conversion layer on said substrate-side electrode with a plasma processing apparatus including a first electrode capable of holding said substrate and a second electrode set to be opposed to said first electrode and provided on a portion opposed to said first electrode with a plurality of gas supply ports formed along concentric circles so that the quantities of gas supplied through said gas supply ports are different from each other on an inner peripheral side and an outer peripheral side; and
forming a rear electrode having conductivity on said photoelectric conversion layer.

2. The method for manufacturing a photovoltaic element according to claim 1, wherein
the step of forming said photoelectric conversion layer includes a step of forming said photoelectric conversion layer by employing said second electrode in which the densities of said plurality of gas supply ports are different from each other on the inner peripheral side and the outer peripheral side.

3. The method for manufacturing a photovoltaic element according to claim 2, wherein
the step of forming said photoelectric conversion layer includes a step of forming said photoelectric conversion layer by employing said second electrode in which the distances between the concentric circles of adjacent said plurality of gas supply ports are different from each other on the inner peripheral side and the outer peripheral side.

4. The method for manufacturing a photovoltaic element according to claim 3, wherein
the step of forming said photoelectric conversion layer includes a step of forming said photoelectric conversion layer in a state where the quantity of supplied gas is larger on the outer peripheral side than on the inner peripheral side of said second electrode by employing said second electrode having said plurality of gas supply ports so provided that the distance between adjacent concentric circles is smaller on the outer peripheral side as compared with that on the inner peripheral side.

5. The method for manufacturing a photovoltaic element according to claim 3, wherein
the step of forming said photoelectric conversion layer includes a step of forming said photoelectric conversion layer in a state where the quantity of supplied gas is larger on the inner peripheral side than on the outer peripheral side of said second electrode by employing said second electrode having said plurality of gas supply ports so provided that the distance between adjacent concentric circles is smaller on the inner peripheral side as compared with that on the outer peripheral side of said second electrode.

6. The method for manufacturing a photovoltaic element according to claim 2, wherein
the step of forming said photoelectric conversion layer includes a step of forming said photoelectric conversion layer by employing said second electrode in which the lengths of arcs connecting adjacent said plurality of gas supply ports provided along the concentric circles with each other are different from each other in the concentric circle on the inner peripheral side and the concentric circle on the outer peripheral side.

7. The method for manufacturing a photovoltaic element according to claim 6, wherein
the step of forming said photoelectric conversion layer includes a step of forming said photoelectric conversion layer by employing said second electrode having said plurality of gas supply ports so provided that the length of an arc connecting adjacent said plurality of gas supply ports provided along the concentric circles of said second electrode is smaller in the concentric circle on the outer peripheral side as compared with the concentric circle on the inner peripheral side of said second electrode.

8. The method for manufacturing a photovoltaic element according to claim 1, wherein
said photoelectric conversion layer is thin-film said photoelectric conversion layer having a photoelectric conversion thin film.

9. The method for manufacturing a photovoltaic element according to claim 8, wherein
the step of forming said photoelectric conversion layer includes steps of forming a first photoelectric conversion layer containing an amorphous silicon semiconductor and forming a second photoelectric conversion layer containing a microcrystalline silicon semiconductor with said plasma processing apparatus.

10. The method for manufacturing a photovoltaic element according to claim 1, wherein
the step of forming said photoelectric conversion layer includes a step of forming said photoelectric conversion layer in a state where the quantities of supplied gas are different from each other on the inner peripheral side and the outer peripheral side by employing said second electrode provided on the portion opposed to said first electrode with a plurality of projecting portions along the concentric circles so that at least one said gas supply port is provided on said projecting portions.

11. A plasma processing apparatus comprising:
a first electrode capable of holding a substrate; and
a second electrode set to be opposed to said first electrode and provided on a portion opposed to said first electrode with a plurality of gas supply ports, wherein
said plurality of gas supply ports are provided along concentric circles, and so arranged that the quantities of supplied gas are different from each other on an inner peripheral side and an outer peripheral side.

12. The plasma processing apparatus according to claim 11, wherein
the densities of said plurality of gas supply ports formed on said second electrode are different from each other on the inner peripheral side and the outer peripheral side.

13. The plasma processing apparatus according to claim 12, wherein
the distances between the concentric circles of said plurality of gas supply ports formed on said second electrode are different from each other on the inner peripheral side and the outer peripheral side.

14. The plasma processing apparatus according to claim 13, wherein
said plurality of gas supply ports formed on said second electrode are provided at equal intervals along the concentric circles.

15. The plasma processing apparatus according to claim 13, wherein
the distance between adjacent concentric circles is smaller on the outer peripheral side as compared with that on the inner peripheral side.

16. The plasma processing apparatus according to claim 13, wherein
the distance between adjacent concentric circles is smaller on the inner peripheral side as compared with that on the outer peripheral side.

17. The plasma processing apparatus according to claim 12, wherein
the lengths of arcs connecting adjacent said plurality of gas supply ports provided along the concentric circles with each other are different from each other in the concentric circle on the inner peripheral side and the concentric circle on the outer peripheral side.

18. The plasma processing apparatus according to claim 17, wherein
the length of an arc connecting adjacent said plurality of gas supply ports provided along the concentric circles is smaller in the concentric circle on the outer peripheral side as compared with the concentric circle on the inner peripheral side.

19. The plasma processing apparatus according to claim 17, wherein
said plurality of gas supply ports are provided along the concentric circles so set that the intervals between adjacent concentric circles are equal to each other.

20. The plasma processing apparatus according to claim 11, wherein
said second electrode is provided on the portion opposed to said first electrode with a plurality of projecting portions along the concentric circles, and at least one said gas supply port is provided in said projecting portions.
